(19) United States
(12) Patent Application Publication
(10) Pub. No.: US 2026/0366896 A1
(43) Pub. Date: Nov. 19, 2026

(54) IMPRINTING APPARATUS, IMPRINTING METHOD, AND ARTICLE MANUFACTURING METHOD

(71) Applicant: CANON KABUSHIKI KAISHA, Tokyo (JP)

(72) Inventor: NAOKI MURASATO, Tochigi (JP)

(21) Appl. No.: 19/650,633

(22) Filed: Apr. 17, 2026

(30) Foreign Application Priority Data
May 13, 2025 (JP) 2025-080555

(51) Int. Cl. G01F 1/00; G03F 7/00

(52) U.S. Cl. CPC G01F 1/00; G03F 7/0002

(57) ABSTRACT

An imprinting apparatus performs an imprinting process of bringing a patterned part of a mold into contact with a resin on a substrate and forming a pattern of the resin on the substrate. The imprinting apparatus includes a mold holding unit configured to attract and hold a rear surface opposite to a surface on which the patterned part has been provided out of surfaces of the mold, a pipe connected to a space between the rear surface of the mold and the mold holding unit, and a flowmeter configured to measure a flow rate of air flowing in the pipe. The imprinting apparatus controls a pressure in a closed space which is defined between the rear surface of the patterned part and the mold holding unit on the basis of a value of the flowmeter in the imprinting process.

### BACKGROUND

### Field of the Technology

The present disclosure relates to an imprinting apparatus, an imprinting method, and an article manufacturing method.

### Description of the Related Art

In optical imprinting technology for manufacturing a semiconductor device or the like, a mold having a pattern formed thereon is imprinted on a silicon substrate on which a photo-curable resin has been applied, and the resin is cured by ultraviolet light to form a pattern.

In an imprinting apparatus, a space between a mold and a silicon substrate is filled with a photo-curable resin and is cured using an ultraviolet exposure unit. At that time, the mold and the silicon substrate are aligned with respect to alignment marks before impression and during impression.

In Japanese Patent Laid-Open No. 2019-165091, an imprinting apparatus that changes a back pressure of a mold patterned part to correct an alignment error due to deformation of a mold is described.

The patterned part is distorted by a magnification correcting mechanism that applies a force to a side surface of the mold. Japanese Patent Laid-Open No. 2019-165091 describes a method of adjusting a pressure applied to a rear surface of the mold according to the force of the magnification correcting mechanism in order to reduce the distortion. However, since a means for detecting an amount of deformation of the mold is not disclosed in Japanese Patent Laid-Open No. 2019-165091, it is difficult to change an amount of correction according to deformation of the mold.

### SUMMARY

In order to solve the aforementioned problem, an embodiment of the present disclosure provides an imprinting apparatus that performs an imprinting process of bringing a patterned part of a mold into contact with a resin on a substrate and forming a pattern of the resin on the substrate, the imprinting apparatus including: a mold holding unit configured to attract and hold a rear surface opposite to a surface on which the patterned part has been provided out of surfaces of the mold; a pipe connected to a space between the rear surface of the mold and the mold holding unit; and a flowmeter configured to measure a flow rate of air flowing in the pipe, wherein a pressure in a closed space which is defined between the rear surface of the patterned part and the mold holding unit is controlled on the basis of a value of the flowmeter in the imprinting process.

Further features of the present disclosure will become apparent from the following description of embodiments with reference to the attached drawings.

### BRIEF DESCRIPTION OF DRAWINGS

FIG. 1 is a diagram illustrating an example of a configuration of an imprinting apparatus according to a first embodiment.

FIG. 2 is a sectional view illustrating an example of a configuration of an imprinting head according to the first embodiment.

FIG. 3 is a bottom view of the imprinting head illustrated in FIG. 2.

FIG. 4 is a sectional view illustrating an example of a hardware configuration of the imprinting head according to the first embodiment.

FIG. 5 is a graph illustrating an example of values of a flowmeter.

FIG. 6 is a sectional view illustrating an example of a hardware configuration of the imprinting head according to the first embodiment.

FIG. 7 is a flowchart illustrating an example of an imprinting process according to the first embodiment.

FIG. 8 is a sectional view illustrating an example of a hardware configuration of an imprinting head according to a second embodiment.

FIG. 9 is a graph illustrating an example of values of a flowmeter.

FIG. 10 is a sectional view illustrating an example of a hardware configuration of the imprinting head according to the second embodiment.

FIG. 11 is a flowchart illustrating an example of an imprinting process according to the second embodiment.

FIG. 12 is a sectional view illustrating an example of a hardware configuration of an imprinting head according to a third embodiment.

FIGS. 13A-13F are diagrams schematically illustrating an example of an article manufacturing method.

### DESCRIPTION OF THE EMBODIMENTS

Hereinafter, with reference to the accompanying drawings, favorable modes of the present disclosure will be described using embodiments. In each diagram, the same reference signs are applied to the same members or elements, and duplicate description will be omitted or simplified.

In this specification and the accompanying drawings, unless mentioned otherwise, directions are described in an XYZ coordinate system in which a direction parallel to a surface of a substrate (or a holding surface holding the substrate) is defined as an XY plane. Directions parallel to an X axis, a Y axis, and a Z axis in the XYZ coordinate system are defined as an X direction, a Y direction, and a Z direction, and rotation around the X axis, rotation around the Y axis, and rotation around the Z axis are defined as θX, θY, and θZ.

Control or driving in the X axis, the Y axis, and the Z axis means control or driving in a direction parallel to the X axis, a direction parallel to the Y axis, and a direction parallel to the Z axis. Control or driving in the θX axis, the θY axis, and the θZ axis means control or driving in rotation around an axis parallel to the X axis, rotation around an axis parallel to the Y axis, and rotation around an axis parallel to the Z axis.

Positions are information that can be identified on the basis of coordinates in the X axis, the Y axis, and the Z axis, and postures are information that can be identified by values of the θX axis, the θY axis, and the θZ axis.

### First Embodiment

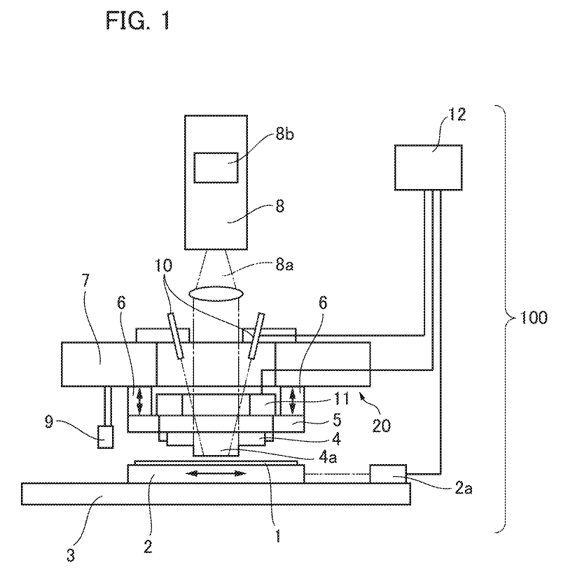

FIG. 1 is a diagram illustrating an example of a configuration of an imprinting apparatus according to a first embodiment. The imprinting apparatus 100 forms patterns in a plurality of shot areas on the substrate by repeating an imprinting cycle (an imprinting process).

In the present embodiment, a shot area means an area of a size corresponding to one patterned part 4a of a mold 4 (mold), that is, an area (a shaping area) in which a pattern of an imprinting material corresponding to the pattern of the mold 4 is formed in one imprinting cycle.

By transferring the pattern of the mold 4 to the imprinting material on the substrate, an element pattern corresponding to the mold pattern is formed on the substrate surface layer. For example, glass, ceramic, metal, semiconductor, or a resin can be used as the material of the substrate 1.

According to necessity, a member formed of a material different from that of the substrate may be provided on the surface of the substrate. The substrate is, for example, a silicon wafer, a compound semiconductor wafer, or a quartz glass wafer.

A substrate stage 2 moves the substrate 1 in the XY direction and a rotation direction in the XY plane and moves the substrate 1 to an imprinting position just below the mold 4. The substrate stage 2 includes a displacement sensor 2a that detects a moving position of the substrate stage 2, and the substrate stage 2 can be driven using a motor on the basis of a detection value thereof and be moved to an accurate position.

The displacement sensor 2a is, for example, a laser interferometer or an encoder. A base frame 3 below the substrate stage 2 performs guidance and holding of the substrate stage 2.

The mold 4 includes a patterned part 4a in which a pattern of a recessed/protruding shape is formed on the surface thereof. By filling a space between the patterned part 4a and the substrate 1 with an imprinting material and curing the imprinting material, the pattern formed in the patterned part 4a is transferred to the substrate 1 (the imprinting material thereof).

The patterned part 4a has a stepped structure coming out (protruding) from an area other than the patterned part 4a of the mold 4 such that the area other than the patterned part 4a of the mold 4 does not come into contact with the substrate 1.

An imprinting head 20 includes a mold holding unit 5 (a mold holding unit) and a drive mechanism 6. The mold holding unit 5 holds the mold 4, is driven up and down (the Z direction), and is also referred to as a mold chuck.

Driving of the mold holding unit 5 can be performed by the drive mechanism 6. The drive mechanism 6 is fixed to a surface plate 7 of a main body of the imprinting apparatus 100 and performs an operation (a contact operation) of bringing the mold 4 into contact with an uncured imprinting material on the substrate.

The contact operation may be performed by raising the substrate 1 or by moving both the substrate 1 and the mold 4. The contact operation may be referred to as an impressing operation.

The imprinting material may also be referred to as an uncured resin. Electromagnetic waves, heat, or the like can be used as the curing energy. For example, light such as infrared light, visible light, or ultraviolet light which is selected from a range of wavelengths of 10 nm to 1 mm can be used as the electromagnetic waves.

The imprinting material may be a composition which is cured by irradiation with light or by heating. Among these, a photo-curable composition which is cured by irradiation with light contains at least a polymerizable compound and a photopolymerization initiator and may further contain a non-polymerizable compound or a solvent according to necessity.

The non-polymerizable compound is at least one selected from a group consisting of a sensitizer, a hydrogen donor, an internally added mold releasing agent, a surfactant, an antioxidant, and polymer components. The viscosity (viscosity at 25°C) of the curable composition may be, for example, equal to or greater than 1 mPa⋅s and equal to or less than 100 mPa⋅s. In this specification, for example, a curable composition which is cured by ultraviolet light is used as the imprinting material.

An irradiation unit 8 irradiates the uncured imprinting material with ultraviolet light 8a via the transparent mold 4 to cure the imprinting material on the substrate. The irradiation unit 8 may include a shutter unit 8b that controls irradiation timings.

[ 0040 ] A dispenser 9 is additionally provided in the surface plate 7. A shot region in which a pattern is formed is moved to below the dispenser 9, and the imprinting material is applied (supplied) to the substrate 1 from the dispenser 9.

A scope 10 includes an optical lens, an illumination, and an image sensor therein and detects a relative misalignment between the mold 4 and an alignment mark on the substrate 1. An amount of misalignment can be corrected by minutely moving the substrate stage 2, and alignment between the mold 4 and the substrate 1 can be performed.

A shape correcting unit 11 (a shape correcting unit) is mounted in the mold holding unit 5. The shape correcting unit 11 can change the shape of the mold by applying a force to side surfaces of the mold 4.

The control unit 12 includes, for example, a processor such as a CPU which is a computer and a storage unit such as a RAM, a ROM, and an HDD. The processor executes a computer program stored in the storage unit to control the operation of the imprinting apparatus 100.

That is, the control unit 12 can control the constituents of the imprinting apparatus 100 to perform a process flow of the imprinting apparatus 100 which will be described later. The control unit 12 controls optimal alignment between the substrate 1 and the mold 4 on the basis of alignment information of the scope 10, position information of the substrate stage 2, and information of a force applied by a mold shape correcting unit.

The control unit 12 controls a pressure of a closed space (a space 4b) on the rear surface of the mold 4 which will be described later on the basis of a value of a flowmeter 13b in the imprinting process.

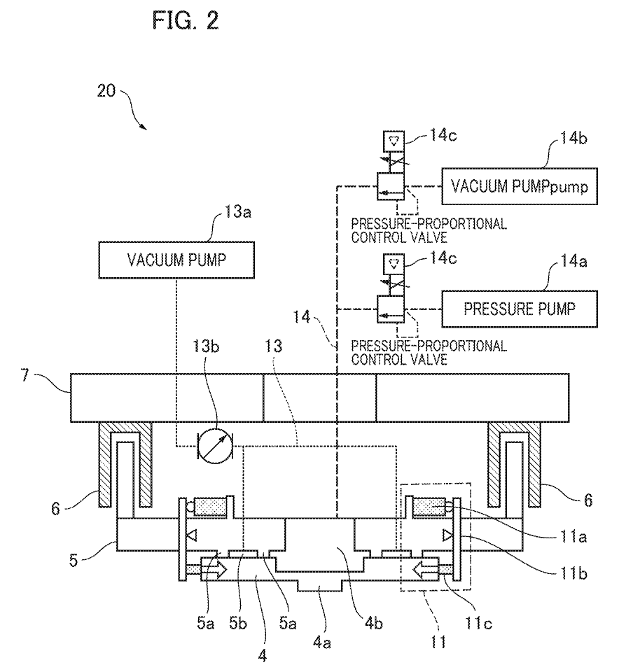

FIG. 2 is a sectional view illustrating an example of a configuration of the imprinting head 20 according to the first embodiment. The mold holding unit 5 holding the mold 4 is provided. The rear surface of the mold 4 and the mold holding unit 5 come into contact with each other in an attraction protruding portion 5a, and a pipe 13 is connected to suction an attraction area 5b (an attraction space) surrounded by a contact part between the attraction protruding portion 5a and the rear surface of the mold 4 by vacuum.

Here, the rear surface of the mold 4 is a surface opposite to the surface of the mold 4 on which the patterned part 4a is provided. The pipe 13 is a vacuum pipe in which an attraction gas for attracting and holding the mold 4 flows. A vacuum pump 13a is connected to the pipe 13, and a flowmeter 13b is provided in the middle and can measure a flow rate of air flowing in the pipe 13.

The mold holding unit 5 and a part of the surface plate 7 of the main body are held via the drive mechanism 6. The drive mechanism 6 is configured as a part generating power and includes, for example, a voice coil motor or a linear shaft motor.

The drive mechanism 6 is preferably constituted by a member having no frictional part and being advantageous in a particle generation risk. In addition, even a drive source having a frictional part such as a rotary motor of a ball screw, an air cylinder, or a piezoelectric actuator can be used as long as countermeasures for particle suction have been taken.

Although not illustrated, a displacement sensor that can detect a position of the mold holding unit 5 relative to the surface plate 7 may be provided.

A shape correcting unit 11 including a drive source 11a, a drive transmitting portion 11b, and a load cell portion 11c is provided in the mold holding unit 5. The shape correcting unit 11 can apply a desired force to side surfaces of the mold to change the shape of the mold.

The force generated by the drive source 11a is converted by the drive transmitting portion 11b in the principle of leverage and is applied to the side surfaces of the mold via the load cell portion 11c.

By using this structure, it is possible to adjust a range of a force generated by the drive source and a force to be applied to the mold according to a support position of the drive transmitting portion 11b. There is also an advantage that the drive source 11a can be disposed on the top surface of the mold holding unit 5 having a relatively empty space.

The structure of the shape correcting unit 11 is not limited thereto, and for example, any structure such as a structure in which a load cell and a drive source are arranged in series may be used as long as a desired force is applied to the side surfaces of the mold.

An enclosed space 4b is provided on the rear side of the mold 4. The space 4b is a closed space which is defined (formed) between (a recessed portion provided in) the rear surface of the mold 4 and the mold holding unit 5 in a state in which the mold 4 is held by the mold holding unit 5.

The space 4b is also referred to as a cavity or a core out and is configured as a cylindrical recessed structure covering the patterned part 4a. The imprinting apparatus 100 includes a seal member such as a seal glass (a glass substrate) for defining the space 4b on the rear side of the mold 4.

The seal member is, for example, a transmissive member that transmits energy (for example, optical energy) for curing an imprinting material. The space 4b is defined by the rear surface of the mold 4, the mold holding unit 5, and the seal member.

In order to control the pressure in the space 4b, a pipe 14 is connected to the space 4b. A pressure pump 14a and a vacuum pump 14b are connected to the pipe 14, and a pressure-proportional control valve 14c for changing the pressure is provided in the middle of the pipe.

The pressure in the enclosed space 4b on the rear surface of the mold can be changed (adjusted) to a desired pressure with the configuration of the pipe 14. In the following description, the pressure in the space 4b may be simply referred to as a back pressure.

Since adjustment of the pressure in the space 4b corresponds to adjustment of a force applied to the rear surface of the mold 4, it is possible to change the shape of the patterned part 4a of the mold 4 held by the mold holding unit 5 by adjusting the pressure in the space 4b.

For example, by adjusting the pressure in the space 4b to a pressure higher than the atmospheric pressure, it is possible to deform the patterned part 4a of the mold 4 to a shape convex toward the substrate. In this way, by adjusting the pressure in the space 4b to a positive pressure or a negative pressure with respect to an external pressure (the atmospheric pressure) around the space 4b, it is possible to continuously deform the patterned part 4a of the mold 4 to a shape convex or concave toward the substrate.

For example, in a state in which the internal pressure of the space 4b has been increased to deform the patterned part 4a of the mold 4 to a convex shape, the mold holding unit 5 is lowered. Accordingly, contact between the patterned part 4a of the mold 4 and the imprinting material on the substrate 1 can be started from the central part of the mold 4.

Thereafter, by decreasing the internal pressure of the space 4b in parallel with additional lowering of the mold 4 (the mold holding unit 5), the patterned part 4a of the mold 4 is made to be close to a planar shape. Accordingly, gas present between the mold 4 (the patterned part 4a) and the substrate 1 is extruded to the outside, and gas entering the imprinting material (bubbles mixed into the imprinting material) on the substrate is reduced.

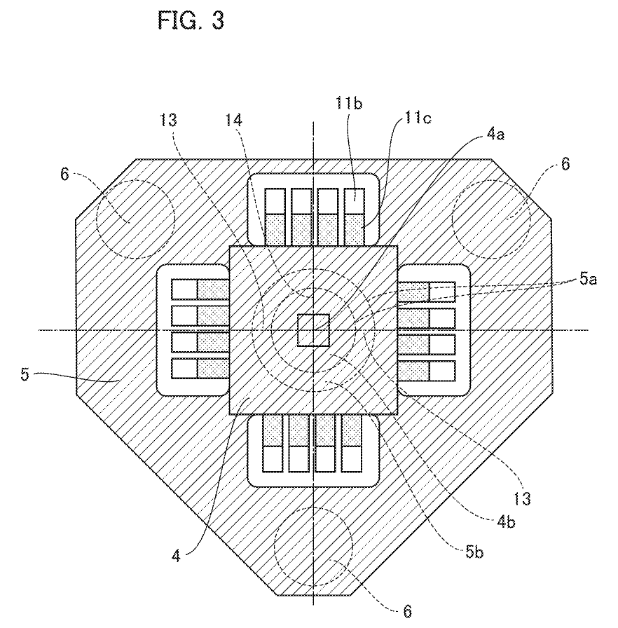

FIG. 3 is a bottom view of the imprinting head 20 illustrated in FIG. 2. As illustrated in FIG. 3, the mold holding unit 5 includes a drive mechanism 6 at three positions, and the mold 4 is attracted and held at the center thereof.

An attraction area 5b is provided on the rear side of the mold 4, and the mold holding unit 5 attracts and holds the rear surface of the mold 4 using a vacuum pressure from the pipe 13. The pipe 13 is connected to the attraction area 5b which is a space between the rear surface of the mold 4 and the mold holding unit 5.

In the present embodiment, a connection port of the pipe 13 is provided at two positions on the left and right sides for the purpose of uniformity in pressure, but the present disclosure is not limited thereto, and the number of connection ports of the pipe 13 is not particularly limited. A connection port of the pipe 14 is provided in the enclosed space 4b inside of the mold 4.

Areas penetrating the mold holding unit 5 are provided around the mold 4, and a plurality of shape correcting units 11 each including a set of the drive source 11a (illustrated in FIG. 2), the drive transmitting portion 11b, and the load cell portion 11c are disposed in the areas.

In the present embodiment, four shape correcting units 11 are uniformly arranged in each side surface of the mold 4, and a total of 16 shape correcting units 11 are used. The number of shape correcting units 11 can be determined on the basis of the size of the mold 4, the deformation shape to be corrected, and an amount of correction.

Although not illustrated, a sensor such as a laser interferometer for measuring a side surface position of the mold 4 and measuring the size or arrangement of the mold 4 may be provided around the mold 4.

In the imprinting apparatus 100 according to the present embodiment, a force can be applied to the mold 4 in four directions of the side surfaces of the mold 4 by the shape correcting units 11. At that time, there is a risk of unintentional deformation (a risk of distortion) of the mold 4 to a shape convex or concave toward the substrate.

There is a problem in that unevenness in deformation of the mold 4 due to geometric errors of the mold 4 or the shape correcting units 11 or a difference in condition between the forces applied to the mold 4 will affect an alignment error, and thus a means for changing an amount of correction according to deformation of the mold at that time needs to be provided.

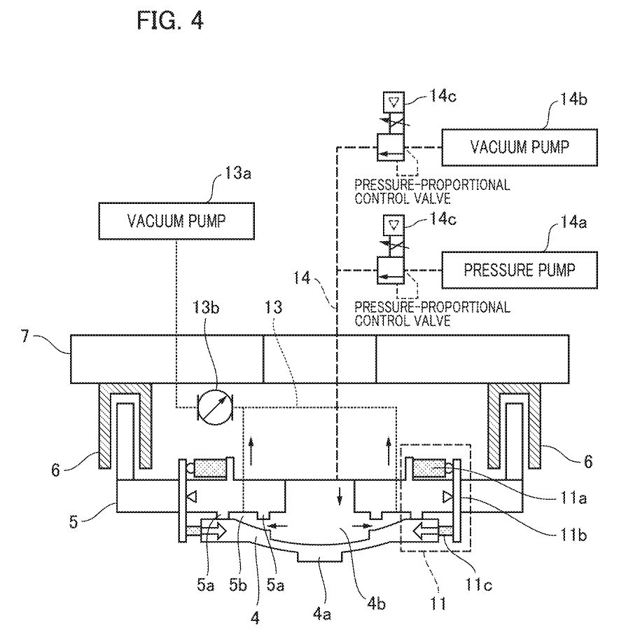

A flow of air flowing in the pipe 13 when deformation of the mold 4 occurs will be described below with reference to FIG. 4. FIG. 4 is a sectional view illustrating an example of a configuration of the imprinting head 20 according to the first embodiment.

Here, a state in which forces have been applied to the mold 4 by the shape correcting units 11 is illustrated, and the mold 4 is deformed. The mold 4 is deformed to a shape convex toward the substrate (a downwardly convex shape) by applying forces to the side surfaces of the shape correcting units 11.

Accordingly, a gap is formed in a boundary between the space 4b and the attraction area 5b, and a flow of air from the pipe 14 passes over the boundary and flows to the attraction area 5b and flows to the pipe 13 as indicated by an arrow. A flow rate at that time can be measured by the flowmeter 13b.

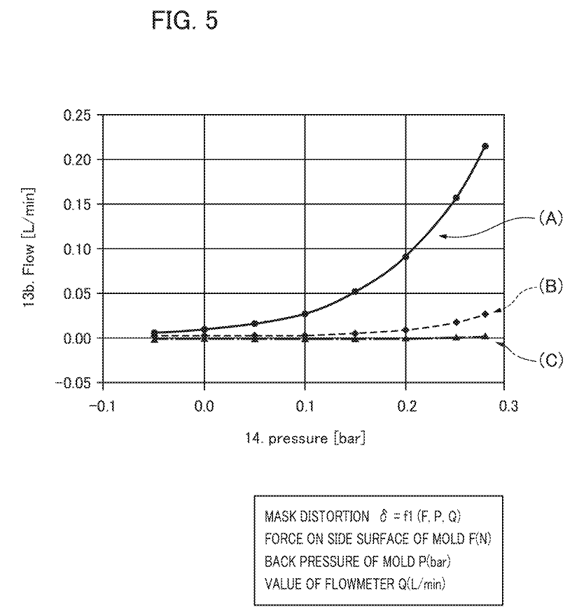

Graphs of values of the flowmeter with distortion of the mold and parameters associated with the distortion of the mold 4 will be described below with reference to FIG. 5. FIG. 5 is a graph illustrating an example of the values of the flowmeter 13b.

Specifically, FIG. 5 illustrates an example of the value of the flowmeter 13b reacting to the pressure value of the pipe 14 as graphs. In FIG. 5, the horizontal axis represents the pressure value from the pipe 14, and the vertical axis represents the measured value (flow rate value) of the flowmeter 13b having detected a flow rate flowing in the pipe 13.

In a state in which constant forces are applied to the mold 4 by the shape correcting units 11, the value of the flowmeter 13b is classified into, for example, plots (A), (B), and (C). (A) is a graph when deformation of the mold 4 by the shape correcting units 11 is large.

In (A), the measured value of the flowmeter 13b is close to 0 L/min when the pressure from the pipe 14 is close to 0 bar, and the measured value of the flowmeter 13b increases to about 0.09 L/min when the pressure from the pipe 14 is set to 0.2 bar. When the pressure from the pipe 14 is additionally increased, the measured value of the flowmeter 13b increases to 0.2 L/min or more.

(B) indicates a plot when deformation of the mold 4 by the shape correcting units 11 is smaller than that in (A). In (B), the measured value of the flowmeter 13b is increased to about 0.025 L/min due to the pressure from the pipe 14 and is a value which is smaller than that in (A) and which can be detected by the flowmeter 13b.

In (C), even when the pressure from the pipe 14 is changed, the measured value of the flowmeter 13b does not change from near 0 L/min, and deformation of the mold 4 can be said not to occur in a detectable range. In this case, it can be seen that the relationship between the pressure from the pipe 14 and the measured value of the flowmeter 13b changes according to the amount of deformation of the mold 4.

Deformation of the mold 4 is also associated with a force F (N) applied from the shape correcting unit 11 to the mold 4. Accordingly, when an amount of deformation of the mold 4 is defined as δ, the pressure of the pipe 14 is defined as P (bar), and the measured value of the flowmeter 13b is defined as Q (L/min), the amount of deformation can be calculated as a function δ=f1(F, P, Q).

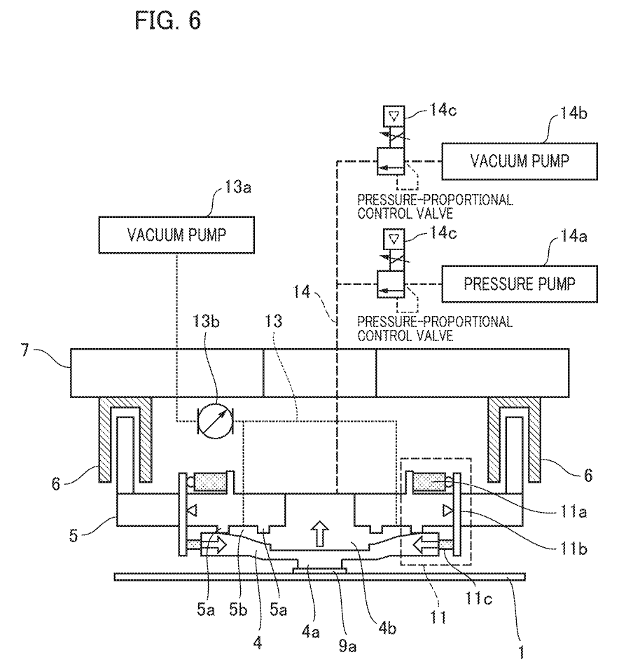

FIG. 6 is a sectional view illustrating an example of a configuration of the imprinting head according to the first embodiment. In the drawing, a cross-section of the imprinting head 20 in a state in which distortion (deformation) of the mold has been corrected when the mold 4 comes into contact with the imprinting material on the substrate 1 is illustrated.

In the imprinting apparatus 100 according to the present embodiment, deformation of the mold 4 is corrected to make the patterned part 4a of the mold 4 approach a planar shape (a flat state) by controlling the pressure of the pipe 14 to a negative pressure when the mold 4 and the imprinting material on the substrate 1 come into contact.

Since the negative pressure P (bar) of the pipe 14 at that time is determined to be proportional to an amount of distortion δ of the mold 4, a function P=f2(δ) is determined in advance for each apparatus, and the negative pressure of the pipe 14 is calculated according to the function.

When the patterned part 4a departs from the flat state, an influence of distortion of the mold 4 appears mainly as an alignment error in the outer peripheral portion of the imprinted pattern, and thus fine correction of the function P=f2(δ) may be performed in consideration of a type of the error.

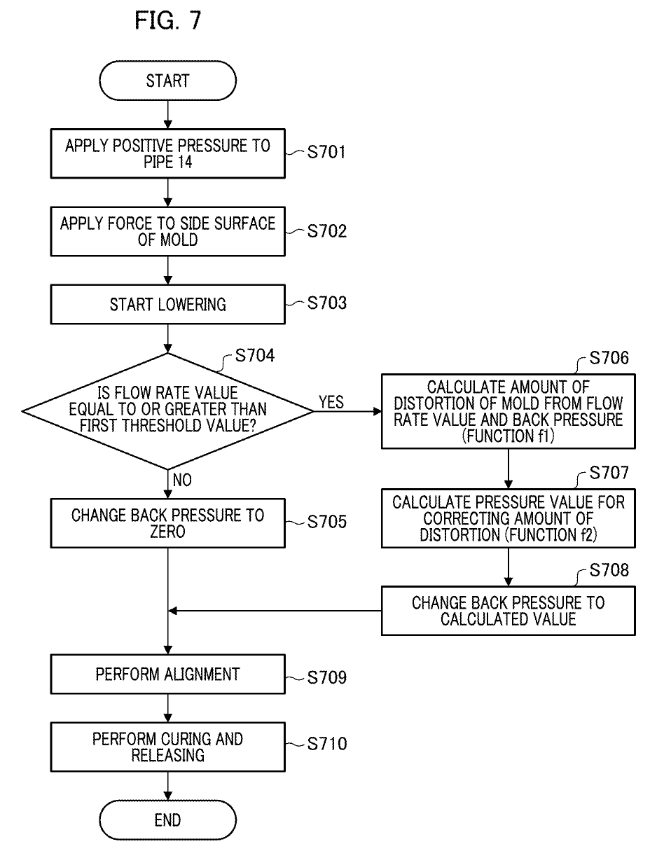

FIG. 7 is a flowchart illustrating an example of an imprinting process according to the first embodiment. This flowchart is an example of a process flow of performing an imprinting process in one imprinting cycle, that is, in one shot region.

Operations of steps in the flowchart illustrated in FIG. 7 are sequentially performed by causing a CPU or the like which is a computer in the control unit 12 to execute a computer program stored in the memory.

In S701, the control unit 12 controls the pressure-proportional control valve 14c of the pressure pump 14a such that a positive pressure is applied to the pipe 14. That is, the internal pressure of the space 4b is increased. In S702, the control unit 12 applies a force on the side surfaces of the mold 4 using the shape correcting units 11.

In S703, the control unit 12 starts downward movement (lowering) of the mold holding unit 5 using the drive mechanism 6 in a state in which the positive pressure of the pipe 14 is maintained. At this time, by decreasing the internal pressure of the space 4b in parallel with additional lowering of the mold holding unit 5 as described above, the patterned part 4a of the mold 4 is made to approach a planar shape.

In S704, the control unit 12 acquires the measured value (flow rate value) of the flowmeter 13b in the pipe 13 and determines whether the measured value of the flowmeter 13b is equal to or greater than a first threshold value (for example, 0.01 L/min).

Here, when the measured value of the flowmeter 13b is less than the first threshold value (NO), the control unit 12 determines that distortion of the mold 4 has not occurred and causes the process flow to proceed to S705. In S705, the control unit 12 controls the pressure-proportional control valve 14c such that the back pressure of the mold 4 is zero. Accordingly, the patterned part 4a of the mold 4 is changed to a planar shape (or a shape close to a planar shape).

On the other hand, when it is determined in S704 that the measured value of the flowmeter 13b is equal to or greater than the first threshold value (YES), the control unit 12 determines that distortion of the mold 4 by the shape correcting units 11 has occurred and causes the process flow to proceed to a calculation step (S706 to S707).

In S706, the control unit 12 calculates an amount of distortion of the mold 4 using the function δ=f1(F, P, Q) on the basis of the measured value Q (L/min) of the flowmeter 13b acquired in S704, the back pressure value, that is, the negative pressure P (bar) of the pipe 14, and the force F (N) applied to the side surfaces of the mold.

This function is determined by preparing the graph illustrated in FIG. 5 in advance for each apparatus. In S707, the control unit 12 calculates the pressure value P using the function P=f2(δ) on the basis of the amount of distortion calculated in S706.

In S708, the control unit 12 applies the pressure value calculated in S706 to the back pressure of the mold 4. That is, the control unit 12 controls the pressure-proportional control valve 14c such that the back pressure of the mold 4 is changed to the pressure value calculated in S707. Accordingly, the deformation of the mold 4 is corrected, and the patterned part 4a is changed to a planar shape (or a shape close to a planar shape).

In S709, in a state in which the patterned part 4a of the mold 4 is brought into contact with the imprinting material on the substrate 1, positions of an alignment mark on the mold 4 and an alignment mark on the substrate 1 are measured by the scope 10, and the control unit 12 performs alignment using the substrate stage 2 such that a desired position is achieved.

In S710, the control unit 12 irradiates the imprinting material on the substrate with ultraviolet light 8a from the irradiation unit 8 via the transparent mold 4 to cure the imprinting material. When curing is completed, the control unit 12 performs a mold releasing operation of raising the mold holding unit 5 using the drive mechanism 6 and releasing (separating) the mold 4 from the imprinting material on the substrate.

Through the aforementioned processes, the pattern of the imprinting material is formed in the shot region. Since the aforementioned flow indicates one imprinting cycle, the imprinting process on all the shot regions on the substrate is completed by repeating S701 to S710 on all the shot regions on the substrate.

S702 may be performed earlier than S701, or S701 and S702 may be performed in parallel.

The measured value of the flowmeter 13b acquired and used for determination in S704 is preferably a value after the shape of the mold 4 has been corrected by the shape correcting units 11 (after S702) and before the alignment is performed (S709).

For example, the measured value of the flowmeter 13b just before downward movement of the mold holding unit 5 by the drive mechanism 6 is started (S703) can be used. In this case, since the force from the shape correcting unit 11 is maximized and the mold holding unit 5 is stopped, there is an advantage that it is easy to detect distortion of the mold 4.

For example, the measured value of the flowmeter 13b just before the alignment is performed (S709) may be used. In this case, since it is the measured value of the flowmeter 13b in a state in which the patterned part 4a of the mold 4 is made to approach a planar shape by decreasing the internal pressure of the space 4b, it is possible to further improve overlap accuracy by correcting the detected distortion.

According to the present embodiment, it is possible to correct distortion of the mold 4 due to correction of the shape of the mold 4 using the shape correcting unit 11 and to improve the overlap accuracy.

In the present embodiment, an example in which distortion of the mold 4 due to the shape correcting unit 11 is corrected has been described, but the present embodiment may also be applied to correction of distortion of the mold 4 itself.

### Second Embodiment

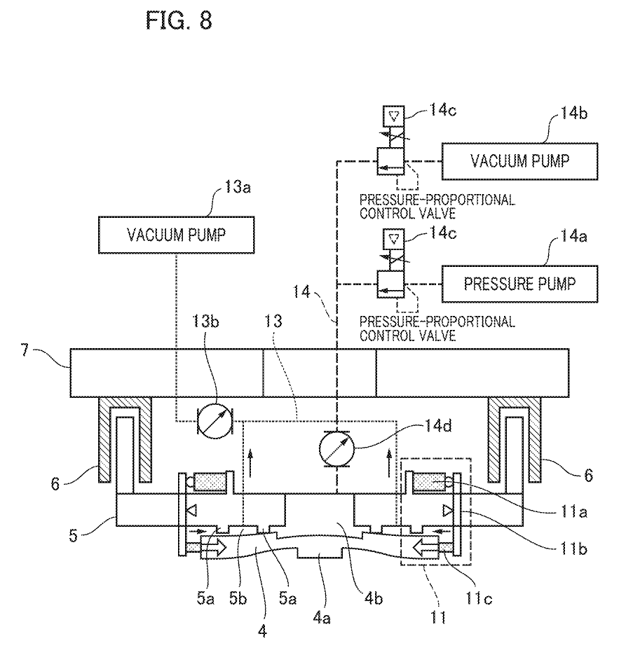

FIG. 8 is a sectional view illustrating an example of a configuration of an imprinting head 20 according to a second embodiment. Here, a state in which a force is applied to a mold 4 by a shape correcting unit 11 is illustrated, and the mold 4 is deformed. Description of the same constituents as in the first embodiment will be omitted.

A flowmeter 14d is provided in a pipe 14 and can measure a flow rate of air which is input to or output from a space 4b on the rear side of the mold 4. By additionally providing the flowmeter 14d, the measured value of the flowmeter 13b can be compared with a measured value of the flowmeter 14d.

Naturally, when deformation of a downward convex shape is generated in the mold 4, a flow of air flowing in the pipe 13 is the same flow of air as illustrated in FIG. 4, there is no position at which the flow of air branches from the pipe 14 to the pipe 13, and the flowmeter 13b and the flowmeter 14d represent the same value.

However, when the mold 4 is deformed in a shape concave toward the substrate (an upward convex shape) as illustrated in FIG. 8, the rear surface of the mold 4 comes into contact with the inner-radius side of the attraction protruding portion 5a, a gap is formed on the outer-radius side, and thus the flow of air flowing in the pipe 13 is a flow of air inhaled from a space on the outside of the mold 4.

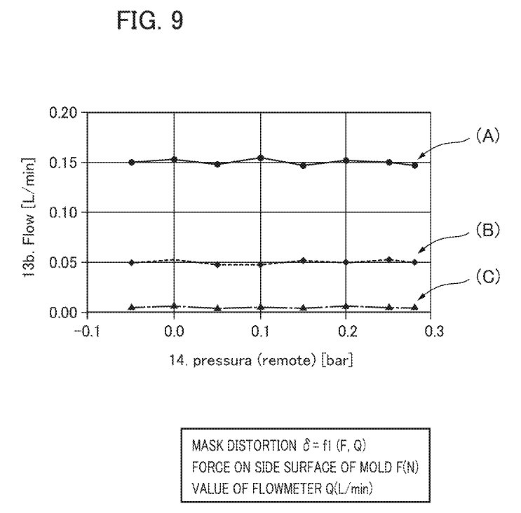

Graphs of values of the flowmeter with distortion of the mold according to the second embodiment and parameters associated with the distortion of the mold 4 will be described below with reference to FIG. 9. FIG. 9 is a graph illustrating an example of the values of the flowmeter 13b.

Specifically, FIG. 9 illustrates an example of the value of the flowmeter 13b reacting to the pressure value of the pipe 14 as graphs when the mold 4 is deformed in an upward convex shape. In FIG. 9, the horizontal axis represents the pressure value from the pipe 14, and the vertical axis represents the measured value (flow rate value) of the flowmeter 13b having detected a flow rate flowing in the pipe 13.

In a state in which constant forces are applied to the mold 4 by the shape correcting units 11, the value of the flowmeter 13b is classified into, for example, plots (A), (B), and (C). (A) is a graph when deformation of the mold 4 by the shape correcting units 11 is large. In (A), the measured value of the flowmeter 13b is a large value close to 0.15 L/min regardless of the pressure value from the pipe 14.

(B) indicates a plot when deformation of the mold 4 by the shape correcting units 11 is smaller than that in (A). In (B), the measured value of the flowmeter 13b is close to 0.05 L/min.

In (C), even when the pressure from the pipe 14 is changed, the measured value of the flowmeter 13b does not change from near 0 L/min, and deformation of the mold 4 can be said to hardly occur in a detectable range.

In this way, when the mold 4 is deformed in an upward convex shape, the mold 4 and the mold holding unit 5 are in contact with each other inside of the attraction area 5b, the pressure from the pipe 14 is not affected, and the flowmeter 13b indicates a value corresponding to a degree of deformation.

Accordingly, a flow of air is not detected by the flowmeter 14d, and the values of the flowmeter 13b and the flowmeter 14d are different. In this way, by adding the flowmeter 14d, it is possible to discriminate deformation of a downward convex shape and deformation of an upward convex shape from the difference between two flow rate values of the flowmeter 13b and the flowmeter 14d.

When it is determined that the mold 4 is deformed in an upward convex shape, the patterned part 4a of the mold 4 can be made to approach a planar shape by controlling the pressure of the pipe 14 to a positive pressure according to the degree of deformation of the mold 4 in order to correct distortion of the mold 4.

When an amount of deformation of the mold 4 is defined as δ and the measured value of the flowmeter 13b is defined as Q (L/min), the amount of deformation of the mold 4 in a convex shape can be calculated as a function δ=f1(F, Q). Since the positive pressure P (bar) of the pipe 14 for correcting the distortion of the mold 4 is determined to be proportional to the amount of distortion δ of the mold 4, a function P=f2(δ) is determined in advance for each apparatus, and the positive pressure of the pipe 14 is calculated according to the function.

When the patterned part 4a departs from the flat state, an influence of distortion of the mold 4 appears mainly as an alignment error in the outer peripheral portion of the imprinted pattern, and thus fine correction of the function P=f2(δ) may be performed in consideration of a type of the error.

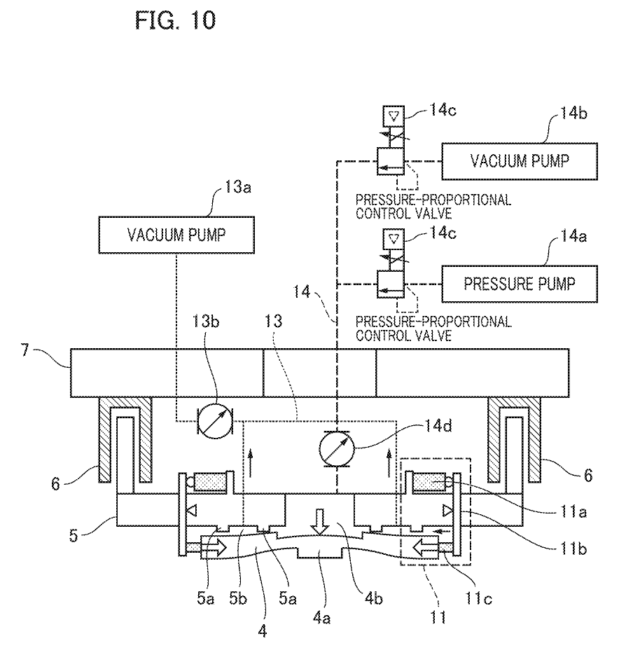

FIG. 10 is a sectional view illustrating an example of a configuration of an imprinting head according to the second embodiment. In the drawing, a state in which deformation of the mold 4 in an upward convex shape has been corrected is illustrated. By filling the space 4b in a pressurizing direction using the pressure-proportional control valve 14c, the patterned part 4a can be changed to a shape close to a flat state.

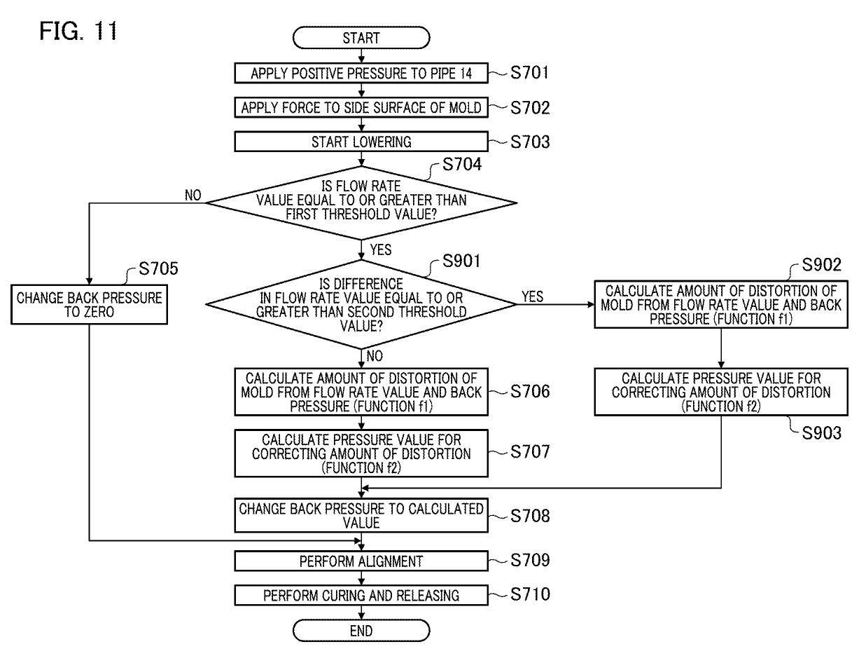

FIG. 11 is a flowchart illustrating an example of an imprinting process according to the second embodiment. This flowchart indicates an example of a process flow of performing an imprinting process in one imprinting cycle, that is, in one shot region.

Herein, description of the same steps as in the flowchart illustrated in FIG. 7 will be omitted. Operations of steps in the flowchart illustrated in FIG. 11 are sequentially performed by causing a CPU or the like which is a computer in the control unit 12 to execute a computer program stored in the memory.

In the present embodiment, when it is determined in S704 that the measured value of the flowmeter 13b is equal to or greater than the first threshold value (YES), the control unit 12 determines that distortion of the mold 4 by the shape correcting units 11 has occurred and causes the process flow to proceed to S901.

In S901, the control unit 12 compares the measured values of the flowmeter 13b and the flowmeter 14d and determines whether a difference between the measured value of the flowmeter 13b and the measured value of the flowmeter 14d is equal to or greater than a second threshold value. Here, when the difference between the flow rate values is less than the second threshold value (NO), the control unit 12 determines that the distortion of the mold 4 has a downward convex shape and causes the process flow to proceed to S706.

On the other hand, when it is determined in S901 that the difference between the flow rate values is equal to or greater than the second threshold value (YES), the control unit 12 determines that the distortion of the mold 4 has an upward convex shape and causes the process flow to proceed to S902.

In S902, the control unit 12 calculates an amount of distortion of the mold 4 using the function δ=f1(F, Q) on the basis of the measured value Q (L/min) of the flowmeter 13b acquired in S704 and the force F (N) applied to the side surfaces of the mold.

This function is determined by preparing the graph illustrated in FIG. 9 in advance for each apparatus. In S903, the control unit 12 calculates the pressure value P using the function P=f2(δ) on the basis of the amount of distortion calculated in S902.

In S708, the control unit 12 applies the pressure value calculated in S706 or S903 to the back pressure of the mold 4. Specifically, when it is determined that the distortion of the mold 4 has a downward convex shape, the control unit 12 controls the pressure-proportional control valve 14c such that the back pressure of the mold 4 is changed to a negative pressure of the pressure value calculated in S706.

When it is determined that the distortion of the mold 4 has an upward convex shape, the control unit 12 controls the pressure-proportional control valve 14c such that the back pressure of the mold 4 is changed to a positive pressure of the pressure value calculated in S903. Accordingly, the deformation of the mold 4 is corrected, and the patterned part 4a is changed to a planar shape (or a shape close to a planar shape).

As described above, by adding a step of comparing the measured values of the flowmeter 13b (a first flowmeter) and the flowmeter 14d (a second flowmeter), it is possible to determine a direction in which deformation of the mold 4 occurs and to discriminate and adjust a correction direction of distortion due to the back pressure.

In the present embodiment, an example in which a flow rate of air input to or output from the space 4b on the rear side of the mold 4 is measured using the flowmeter 14d provided in the pipe 14 and is compared with a flow rate of air flowing in the pipe 13 has been described.

However, by calculating a flow rate of air input to or output from the space 4b on the rear side of the mold 4 on the basis of the parameter of the pressure value applied to the space 4b on the rear side or the like and comparing the calculated flow rate value with that of the flowmeter 13b, the direction of the distortion shape of the mold 4 may be determined. In this case, even when the flowmeter 14d is not provided, it is possible to determine the direction of the distortion shape of the mold 4.

### Third Embodiment

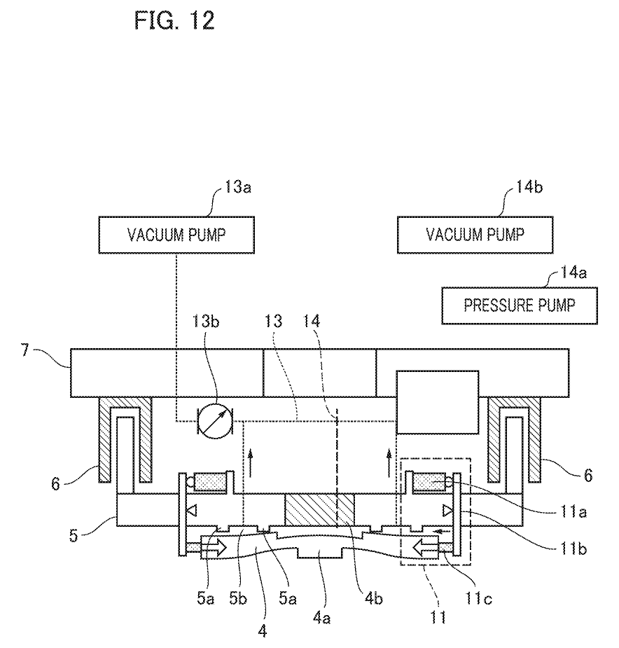

FIG. 12 is a sectional view illustrating an example of a configuration of an imprinting head 20 according to a third embodiment. In the present embodiment, a thickness of a glass substrate in the mold holding unit 5 constituting a top portion of a space 4b on the rear side of the mold 4 is larger than that in the aforementioned embodiment.

In the aforementioned embodiments, the glass substrate has a thickness which can endure the pressure of the space 4b, and the thickness ranges from about 3 mm to 5 mm. In the present embodiment, a thick glass 15 which is the glass substrate forming the space 4b on the rear side of the mold 4 has a thickness equivalent to that of the mold holding unit 5 and has, for example, a thickness of about 15 mm.

Accordingly, since the volume of the space 4b can be reduced to a half or less and a flow rate of air input to or output from the space 4b may be small until the internal pressure of the space 4b is changed, it is possible to shorten the time required for completion of change of the pressure.

The pressure-proportional control valve 14c is preferably disposed as close to the space 4b as possible, whereby it is possible to shorten the length of the pipe 14 and to transmit pressure waves applied into the pipe to the space 4b as at a small distance as possible.

In the present embodiment, the pressure-proportional control valve 14c is disposed in the surface plate 7 of the main body. Accordingly, it is possible to shorten the time required for change of the pressure. The time generally required for change of the pressure is about 0.2 seconds in one change cycle, but the time can be shortened to about 0.1 seconds by employing this application example.

In the imprinting apparatus 100, since three or four times of change of the pressure are performed for each imprinting process, it is possible to reduce a total process time until the imprinting process on all the shot regions of one substrate is completed by 10% to 20%.

In the aforementioned embodiments, the attraction protruding portion 5a is provided at two positions, that is, double circles, and one attraction area 5b is provided, but the number of attraction areas 5b can be increased by increasing the number of attraction protruding portions 5a.

By connecting the vacuum pipe 13 with the flowmeter 13b provided therein to each of the plurality of attraction areas 5b, it is possible to increase the number of flowmeters 13b and to more accurately detect deformation of the mold 4.

### Embodiment of article manufacturing method

A pattern of a cured structure formed by the imprinting apparatus is used permanently as at least a part of various articles or temporarily at the time of manufacturing various articles. An article is an electrical circuit device, an optical device, an MEMS, a recording device, a sensor, or a mold.

Examples of the electrical circuit device include volatile or nonvolatile semiconductor memories such as a DRAM, an SRAM, a flash memory, and an MRAM and semiconductor devices such as an LSI, a CCD, an image sensor, and an FPGA. Examples of the mold include a mold for imprinting.

The pattern of a cured structure is used as a constituent member of at least a part of the article without any change or is temporarily used as a resist mask. After etching, ion implantation, or the like has been performed in a wafer processing step, the resist mask is removed.

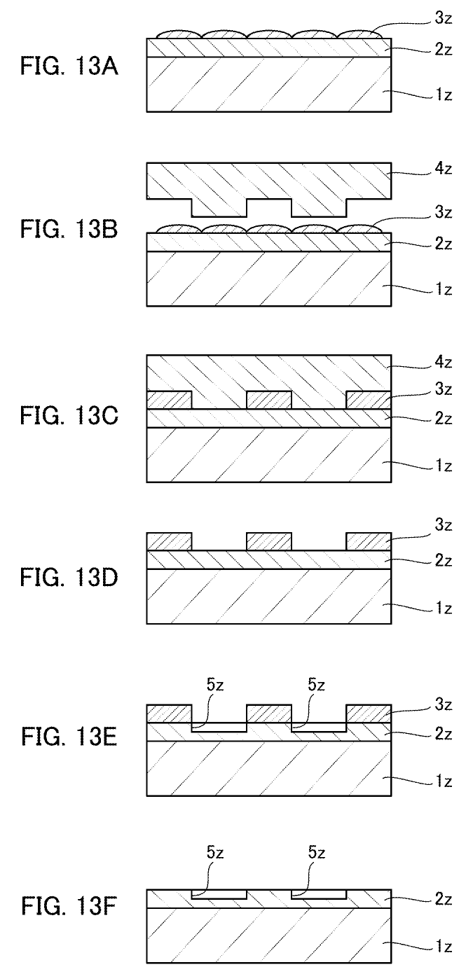

An example of a specific article manufacturing method will be described below with reference to FIGS. 13A-13E. As illustrated in FIG. 13A, a wafer 1z (a substrate) such as a silicon wafer in which a processing material 2z such as an insulator has been formed on the surface is prepared, and an imprinting material 3z is applied to the surface of the processing material 2z using an ink jet method or the like. Here, a state in which the imprinting material 3z with a shape of a plurality of droplets is applied to the wafer is illustrated.

As illustrated in FIG. 13B, a mold 4z for imprinting is disposed such that a surface on which a recessed/protruding pattern has been formed faces the imprinting material 3z on the wafer. As illustrated in FIG. 13C, the wafer 1z to which the imprinting material 3z has been applied is brought into contact with the mold 4z, and a pressure is applied thereto.

A gap between the mold 4z and the processing material 2z is filled with the imprinting material 3z. When light which is curing energy is applied via the mold 4z in this state, the imprinting material 3z is cured.

As illustrated in FIG. 13D, when the mold 4z and the wafer 1z are separated after the imprinting material 3z has been cured, a pattern of a cured structure of the imprinting material 3z is formed on the wafer 1z.

This pattern of a cured structure has a shape in which a recessed part of the mold corresponds to a protruding part of the cured structure and a protruding part of the mold corresponds to a recessed part of the cured structure, that is, a recessed/protruding pattern of the mold 4z is transferred to the imprinting material 3z.

As illustrated in FIG. 13E, when etching is performed using the pattern of the cured structure as an etching-resistant mask, a part having no cured structure or having a cured structure remaining thin on the surface of the processing material 2z is removed to be a groove 5z.

As illustrated in FIG. 13F, when the pattern of the cured structure is removed, an article in which the groove 5z is formed on the surface of the processing material 2z can be obtained. The pattern of the cured structure is removed herein, but the pattern of the cured structure may not be removed after the processing and may be used as, for example, an interlayer insulating film included in a semiconductor device, that is, a constituent member of an article.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

In addition, as a part or the whole of the control according to the embodiments, a computer program realizing the function of the embodiments described above may be supplied to the imprinting apparatus or the like through a network or various storage media. Then, a computer (or a CPU, an MPU, or the like) of the imprinting apparatus or the like may be configured to read and execute the program. In such a case, the program and the storage medium storing the program configure the present disclosure.

In addition, the present disclosure includes those realized using at least one processor or circuit configured to perform functions of the embodiments explained above. For example, a plurality of processors may be used for distribution processing to perform functions of the embodiments explained above.

This application claims the benefit of Japanese Patent Application No. 2025-080555, filed on May 13, 2025, which is hereby incorporated by reference herein in its entirety.

What is claimed is:

1. An imprinting apparatus that performs an imprinting process of bringing a patterned part of a mold into contact with a resin on a substrate and forming a pattern of the resin on the substrate, the imprinting apparatus comprising:
a mold holding unit configured to attract and hold a rear surface opposite to a surface on which the patterned part has been provided out of surfaces of the mold;
a pipe connected to a space between the rear surface of the mold and the mold holding unit;
a flowmeter configured to measure a flow rate of air flowing in the pipe;
at least one processor; and
a memory coupled to the at least one processor, the memory storing instructions that, when executed by the at least one processor, cause the at least one processor to perform:
controlling a pressure in a closed space which is defined between the rear surface of the patterned part and the mold holding unit on the basis of a value of the flowmeter in the imprinting process.

2. The imprinting apparatus according to claim 1, further comprising a shape correcting unit configured to correct a shape of the mold by applying a force to a side surface of the mold,
wherein the pressure in the closed space is controlled on the basis of the value of the flowmeter after the shape of the mold has been corrected by the shape correcting unit at the time of control of the pressure.

3. The imprinting apparatus according to claim 2, wherein the pressure in the closed space is controlled on the basis of the value of the flowmeter before the mold and the substrate are aligned in a state in which the patterned part has been brought into contact with the resin at the time of control of the pressure.

4. The imprinting apparatus according to claim 2, wherein the pressure in the closed space is controlled on the basis of the value of the flowmeter before the mold holding unit is lowered to bring the patterned part into contact with the resin at the time of control of the pressure.

5. The imprinting apparatus according to claim 1, wherein the flowmeter measures a flow rate in a pipe in which attraction gas for attracting and holding the mold flows.

6. The imprinting apparatus according to claim 5, wherein, when the value of the flowmeter that measures a flow rate in the pipe in which the attraction gas flows is equal to or greater than a first threshold value, a pressure for correcting a shape of the mold is applied to the closed space when the patterned part is brought into contact with the resin at the time of control of the pressure.

7. The imprinting apparatus according to claim 1, wherein the flowmeter includes a first flowmeter that measures a flow rate in a pipe in which attraction gas for attracting and holding the mold flows and a second flowmeter that measures a flow rate in a pipe in which a gas for changing the pressure in the closed space flows, and
wherein a deformation direction of the mold is determined on the basis of a difference between a value of the first flowmeter and a value of the second flowmeter at the time of control of the pressure.

8. The imprinting apparatus according to claim 7, wherein, when the difference between the value of the first flowmeter and the value of the second flowmeter is equal to or greater than a second threshold value, a positive pressure is applied to the closed space when the patterned part is brought into contact with the resin at the time of control of the pressure, and
wherein, when the difference between the value of the first flowmeter and the value of the second flowmeter is less than the second threshold value, a negative pressure is applied to the closed space when the patterned part is brought into contact with the resin.

9. The imprinting apparatus according to claim 1, wherein a shape of the patterned part is changed by controlling the pressure in the closed space at the time of control of the pressure.

10. The imprinting apparatus according to claim 1, wherein an amount of change of the mold is calculated on the basis of at least a force applied to a side surface of the mold and the value of the flowmeter at the time of control of the pressure.

11. The imprinting apparatus according to claim 10, wherein the amount of change of the mold is calculated additionally on the basis of the pressure in the closed space at the time of control of the pressure.

12. The imprinting apparatus according to claim 1, wherein the closed space is defined by the rear surface of the mold, the mold holding unit, and a glass substrate, and
wherein the glass substrate has a thickness equal to that of the mold holding unit.

13. The imprinting apparatus according to claim 1, further comprising a plurality of flowmeters,
wherein the pressure in the closed space is controlled on the basis of values of the plurality of flowmeters at the time of control of the pressure.

14. The imprinting apparatus according to claim 1, further comprising a surface plate to which a drive mechanism for driving the mold holding unit is fixed,
wherein a control valve for controlling the pressure in the closed space is disposed in the surface plate.

15. An imprinting method of performing an imprinting process of bringing a patterned part of a mold into contact with a resin on a substrate and forming a pattern of the resin on the substrate, the imprinting method comprising:
measuring a flow rate of air flowing in a pipe connected to a space between a mold holding unit configured to attract and hold a rear surface opposite to a surface on which the patterned part has been provided out of surfaces of the mold and the rear surface of the mold in the imprinting process; and
controlling a pressure in a closed space which is defined between the rear surface of the patterned part and the mold holding unit on the basis of a measured value.

16. An article manufacturing method comprising:
forming a pattern of a cured imprinting material on a substrate using the imprinting method according to claim 15; and
processing the substrate on which the pattern has been formed.
